(19) United States
(12) Patent Application Publication
(10) Pub. No.: US 2012/0056150 A1
(43) Pub. Date: Mar. 8, 2012

(54) NITRIDE SEMICONDUCTOR LIGHT-EMITTING DEVICE WITH ELECTRODE PATTERN

(75) Inventors: Jin Bock LEE, Osan (KR); Dong Woohn Kim, Suwon (KR); Sang Ho Yoon, Yongin (KR); Pun Jae Choi, Yongin (KR)

(73) Assignee: Samsung LED Co., Ltd., Gyunggi-do (KR)

(21) Appl. No.: 13/292,774

(22) Filed: Nov. 9, 2011

Related U.S. Application Data
(62) Division of application No. 12/252,660, filed on Oct. 16, 2008.

(30) Foreign Application Priority Data
Dec. 20, 2007 (KR) 10-2007-0134581

(51) Int. Cl. H01L 33/04

(52) U.S. Cl. 257/9; 257/E33.008

(57) ABSTRACT

A nitride semiconductor light-emitting device with an electron pattern that applies current uniformly to an active layer to improve light emission efficiency is provided. The nitride semiconductor light-emitting device includes multiple layers of a substrate, an n-type nitride layer, an active layer of a multi-quantum-well structure, and a p-type nitride layer. The nitride semiconductor light-emitting device further includes a p-electrode pattern and an n-electrode pattern. The p-electrode pattern includes one or more p-pads disposed on the p-type nitride layer, and one or more p-fingers extending from the p-pads. The n-electrode pattern includes one or more n-pads disposed on an exposed region of the n-type nitride layer to correspond to the p-pads, and one or more n-fingers extending from the n-pads. The n-fingers have identical resistance, and the p-fingers have identical resistance to improve current spreading to the active layer.

### CROSS-REFERENCE TO RELATED APPLICATIONS

This application claims the priority of Korean Patent Application No. 2007-134581 filed on Dec. 20, 2007, in the Korean Intellectual Property Office, the disclosure of which is incorporated herein by reference.

### BACKGROUND OF THE INVENTION

1. Field of the Invention

The present invention relates to a nitride semiconductor light-emitting device, and more particularly, to a nitride semiconductor light-emitting device with an electron pattern that applies current uniformly to an active layer to improve light emission efficiency.

2. Description of the Related Art

A light-emitting diode (LED) is a nitride semiconductor light-emitting device that emits light by recombination of electrons and holes. LEDs are widely used as light sources in optical communication devices, electronic devices, and the like.

In an LED, the frequency (or wavelength) of emitted light is a function of a band gap of a material of the semiconductor device. That is, an LED formed of a semiconductor material with a narrow band gap emits photons of low energy and long wavelengths. Conversely, an LED formed of a semiconductor material with a wide band gap emits photons of short wavelengths.

For example, aluminum gallium indium phosphide (AlGaInP) generates light in the red wavelength range, and silicon carbide (SiC) and a group III nitride-based semiconductor, particularly gallium nitride (GaN), generate light in the blue or ultraviolet wavelength range.

Among these, a gallium-based LED requires a substrate, typically a sapphire substrate, which is appropriate for crystal growth of the gallium nitride (GaN) because it is impossible to form a bulk single crystal of the gallium nitride (GaN).

FIG. 1A is a plan view of a related art flip-chip type nitride LED, and FIG. 1B is a cross-sectional view taken along line A-A in FIG. 1A. An exemplary method for fabricating the related art LED 20 is as follows. A buffer layer 22, an n-type gallium nitride (GaN) clad layer 23A, an active layer 23B, and a p-type gallium nitride (GaN) clad layer 23C are sequentially formed on a sapphire substrate 21. A dry etching is performed on the active layer 23B and the p-type gallium nitride (GaN) clad layer 23C to expose a portion of the n-type gallium nitride (GaN) clad layer 23A. An n-electrode 26 is formed on the exposed portion of the n-type gallium nitride (GaN) clad layer 23A. A transparent electrode 24 is formed on the p-type gallium nitride (GaN) clad layer 23C, and a p-electrode 25 is formed on the transparent electrode 24.

Then, micro-bumps 27 and 28 are formed of gold (Au) or a gold alloy on the p-electrode 25 and the n-electrode 26, respectively.

The LED 20 is mounted on amount substrate, a lead frame or the like by flipping the LED 20 of FIG. 1B and bonding the micro-bumps 27 and 28 of the LED 20 thereto.

The related art LED has been improved in terms of the light emission efficiency by forming an irregular surface of the active layer or by reducing the size of the electrode to increase the light-emitting area. However, these approaches have certain limitations that lead to processing difficulties.

Particularly, the n-electrode of a vertical type nitride LED must be decreased in size because it is disposed on a surface for emitting light. However, decreasing the size of the n-electrode is accompanied by an increased driving voltage and a reduced current spreading effect, which can render the active layer for emitting light useless.

### SUMMARY OF THE INVENTION

An aspect of the present invention provides a nitride semiconductor light-emitting device with an electrode pattern that improves current spreading to an active layer.

According to an aspect of the present invention, there is provided a nitride semiconductor light-emitting device with multiple layers of a substrate, an n-type nitride layer, an active layer of a multi-quantum-well structure, and a p-type nitride layer, the nitride semiconductor light-emitting device including: a p-electrode pattern including one or more p-pads disposed on the p-type nitride layer, and one or more p-fingers extending from the p-pads; and an n-electrode pattern including one or more n-pads disposed on an exposed region of the n-type nitride layer to correspond to the p-pads, and one or more n-fingers extending from the n-pads, wherein the n-fingers have identical resistance, and the p-fingers have identical resistance to improve current spreading to the active layer.

Each of the p-fingers may satisfy the following relation,

R=ρL/A,

where R, ρ, L and A are a resistance, a resistivity, a length, and a cross-sectional area of the p-finger, respectively, so that the cross-sectional area is proportional to the length L.

The p-fingers may include: a first p-finger having a first length and a first cross-sectional area; and a second p-finger having a second length greater than the first length, wherein a second cross-sectional area A2 of the second p-finger satisfies the following relation,

$$\frac{L 1}{A 1} = \frac{L 2}{A 2} ,$$

where L1, L2, A1 and A2 are the first length, the second length, the first cross-sectional area and the second cross-sectional area, respectively.

Each of the n-fingers may satisfy a relation, R=ρL/A, where R, ρ, L and A are a resistance, a resistivity, a length, and a cross-sectional area of the n-finger, respectively, so that the cross-sectional area is proportional to the length L.

The n-fingers include: a first n-finger having a first length and a first cross-sectional area; a second n-finger having a second length greater than the first length; and a third n-finger having a third length greater than the second length, wherein a second cross-sectional area of the second p-finger and a third cross-sectional area of the third p-finger satisfy the following relation,

$$\frac{L 11}{A 11} = \frac{L 12}{A 12} = \frac{L 13}{A 13} ,$$

where L11, L12, L13, A11, A12 and A13 are the first length, the second length, the third length, the first cross-sectional area, the second cross-sectional area and the third cross-sectional area, respectively.

The nitride semiconductor light-emitting device may have a horizontal type structure, and the n-fingers and the p-fingers may be disposed alternatingly and have at least one bent section, respectively.

According to another aspect of the present invention, there is provided a nitride semiconductor light-emitting device including: an active layer having a multi-quantum-well structure between an n-type nitride layer and a p-type nitride layer; a p-electrode pattern including one or more p-pads disposed on the p-type nitride layer, and one or more p-fingers extending from the p-pads; and an n-electrode pattern including one or more n-pads disposed on an exposed region of the n-type nitride layer, and one or more n-fingers extending from the n-pads, wherein the n-fingers have identical resistance, and the p-fingers have identical resistance to improve current spreading to the active layer.

The p-fingers or the n-fingers may include a plurality of fingers extending alternately and radially.

The n-fingers or the p-fingers each may have at least one bent section.

### BRIEF DESCRIPTION OF THE DRAWINGS

The above and other aspects, features and other advantages of the present invention will be more clearly understood from the following detailed description taken in conjunction with the accompanying drawings, in which:

FIG. 1A is a plan view of a related art nitride light-emitting diode (LED);

FIG. 1B is a cross-sectional view taken along the line A-A of FIG. 1A;

FIG. 2 is a schematic view of electrode patterns of a horizontal type nitride semiconductor light-emitting device according to an embodiment of the present invention;

FIG. 3 is a schematic view of electrode patterns of a horizontal type nitride semiconductor light-emitting device according to another embodiment of the present invention;

FIG. 4 is a schematic view of electrode patterns of a horizontal type nitride semiconductor light-emitting device according to still another embodiment of the present invention;

FIG. 5 is a schematic view of an electrode pattern of a vertical type nitride semiconductor light-emitting device according to even another embodiment of the present invention;

FIG. 6 is a schematic view of an electrode pattern of a vertical type nitride semiconductor light-emitting device according to yet another embodiment of the present invention; and

FIG. 7 is a schematic view of an electrode pattern of a vertical type nitride semiconductor light-emitting device according to further another embodiment of the present invention.

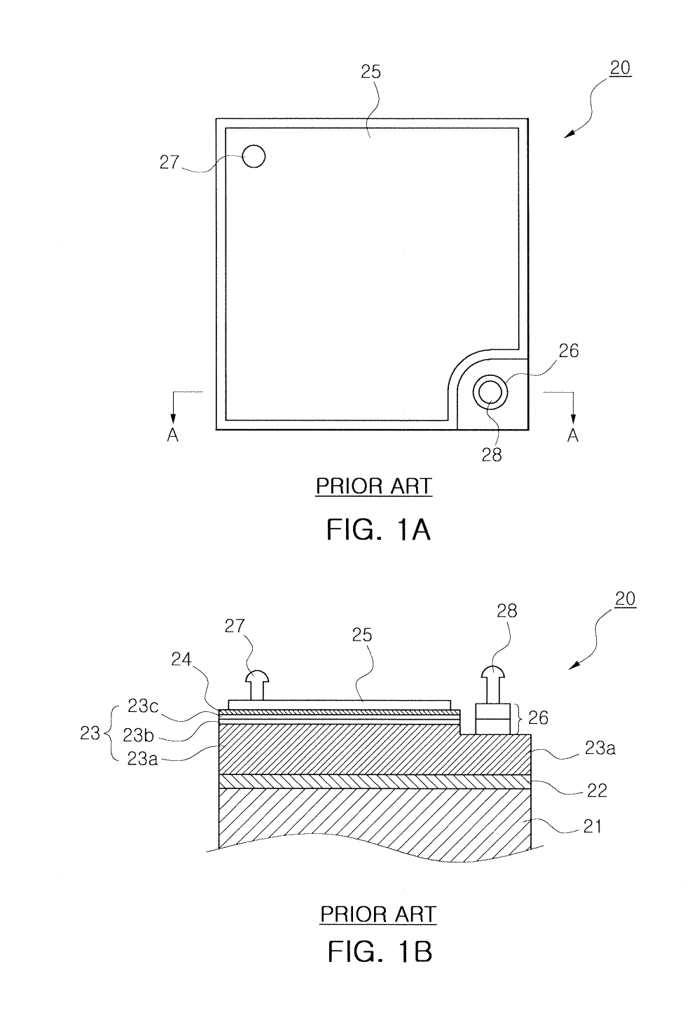

### DETAILED DESCRIPTION OF THE PREFERRED EMBODIMENT

Exemplary embodiments of the present invention will now be described in detail with reference to the accompanying drawings.

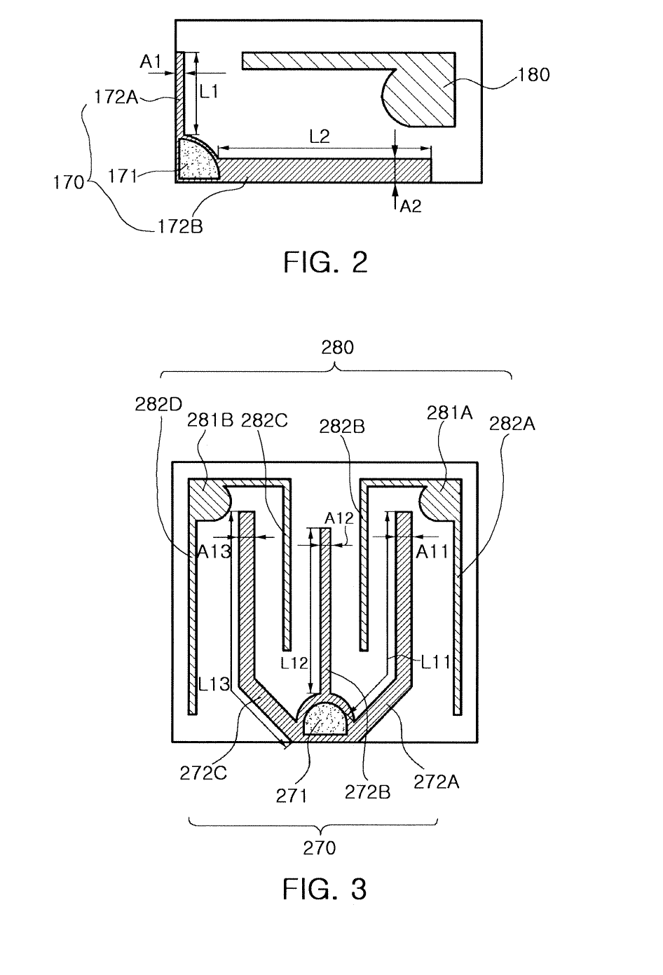

FIG. 2 is a schematic view of electrode patterns of a horizontal type nitride semiconductor light-emitting device according to an embodiment of the present invention. FIG. 2 illustrates a p-electrode pattern disposed on a p-type nitride layer (not shown) and an n-electrode pattern disposed on an exposed region of an n-type nitride layer in a horizontal type nitride semiconductor light-emitting device. Here, well-known configurations or functions of the nitride semiconductor light-emitting device will not be described in detail when they would obscure the subject matter of the invention.

Referring to FIG. 2, the horizontal type nitride semiconductor light-emitting device may include the p-electrode pattern 180 and the n-electrode pattern 170. The p-electrode pattern 180 may be disposed on the p-type nitride layer (not shown) . The n-electrode pattern 170 may include an n-pad 171 disposed on the exposed region of the n-type nitride layer (not shown) to correspond to the p-electrode pattern 180. The n-electrode pattern 170 may further include two n-fingers 172A and 172B.

In more detail, the n-electrode pattern 170 may include the n-pad 171 corresponding to the p-electrode pattern 180, and a first n-finger 172A and a second n-finger 172B that extend from the n-pad 171 along the respective edges of the horizontal type nitride semiconductor light-emitting device.

For example, the first n-finger 172A may extend along the shorter edge of the horizontal type nitride semiconductor light-emitting device, and the second n-finger 172B may extend along the longer edge of the horizontal type nitride semiconductor light-emitting device.

The first n-finger 172A and the second n-finger 172B may have different lengths from each other. That is, the second n-finger 172B may be longer than the first n-finger 172A. In this case, the second n-finger 172B has greater resistance than the first n-finger 172A has because the resistance increases with the length. Therefore, in order to make the first and second n-fingers 172A and 172B have the same resistance R, cross-sectional areas thereof needs to be controlled properly.

The resistance of the finger is expressed as

R=ρL/A (1)

where ρ, L and A are a resistivity, a length, and a cross-sectional area, respectively.

Considering Equation 1, in order to make the n-fingers 172A and 172B have the same resistance, the lengths and the cross-sectional areas of the n-fingers 172A and 172B of the same material, i.e., of the same resistivity need to be controlled to satisfy the following relation

$$\frac{L 1}{A 1} = \frac{L 2}{A 2} \qquad ( 2 )$$

where L1 and L2 are lengths of the first and second n-fingers 172A and 172B, respectively, and A1 and A2 are cross-sectional areas of the first and second n-fingers 172A and 172B, respectively.

Accordingly, if the second n-finger 1723 is longer than the first n-finger 172A as shown in FIG. 2, the cross-sectional area A2 of the second n-finger 1723 is controlled to be greater than the cross-sectional area A1 of the first n-finger 172A so that the first and second n-fingers 172A and 1723 have the same resistance. As such, it is possible to uniformly apply the same current uniformly across the first and second n-fingers 172A and 172B so that the current spreading to the active layer (not shown) can be improved. This is the same to the p-electrode pattern 180.

In summary, as the first and second n-fingers 172A and 1723 have the same resistance, the current can be applied uniformly to the first and second n-fingers 172A and 1723, particularly, even to the ends of the first and second n-fingers 172A and 172B. As such, it is possible to improve the current spreading to the active layer and thus the light emission efficiency of the horizontal type nitride semiconductor light-emitting device.

Hereinafter, electrode patterns of a horizontal type nitride semiconductor light-emitting device according to another embodiment of the present invention will be described with reference to FIG. 3.

FIG. 3 is a schematic view of the electrode patterns of the horizontal type nitride semiconductor light-emitting device according to the embodiment. FIG. 3 illustrates a p-electrode pattern 280 disposed on a p-type nitride layer (not shown) and an n-electrode pattern 270 disposed on an exposed region of an n-type nitride layer in the horizontal type nitride semiconductor light-emitting device.

Referring to FIG. 3, the horizontal type nitride semiconductor light-emitting device may include the p-electrode pattern 280 disposed on the p-type nitride layer (not shown), and the n-electrode pattern 270 disposed on the exposed region of the n-type nitride layer (not shown). The p-electrode pattern 280 may include first and second p-pads 281A and 281B, first and second p-fingers 282A and 282B extending from the first p-pad 281A, and third and fourth p-fingers 282C and 282D extending from the second p-pad 281B. The n-electrode pattern 270 may include an n-pad 271 corresponding to the p-pads 281A and 281B, and first, second and third n-fingers 272A, 272B and 272C.

The n-fingers 272A, 272B and 272C and the p-fingers 282A, 282B, 282C and 282D may extend alternatingly from the n-pad 271 and the p-pads 281A and 281B, respectively.

In more detail, the first n-finger 272A may slope up and then extend vertically between the first p-finger 282A and the second p-finger 282B. The second n-finger 272B may extend vertically between the second p-finger 282B and the third p-finger 282C. The third n-finger 272C may slope up and the extend vertically between the third p-finger 282C and the fourth p-finger 282D.

Here, the first to third n-fingers 272A, 272B and 272C may have different lengths L11, L12 and L13, respectively. For example, the first n-finger 272A and the third n-finger 272C may be longer than the second n-finger 272B. In such a case, the first n-finger 272A and the third n-finger 272C has greater resistance than the second n-finger 272B because the resistance increases with the length. Therefore, in order to make the n-fingers 272A, 272B and 272C have the same resistance R, cross-sectional areas thereof need to be controlled properly on the basis of Equation 1, as described above. That is, the lengths and the cross-sectional areas of the n-fingers 272A, 272B and 272C of the same material, i.e., of the same resistivity need to be controlled to satisfy the following relation

$$\frac{L 11}{A 11} = \frac{L 12}{A 12} = \frac{L 13}{A 13} \qquad ( 3 )$$

where L11, L12 and L13 are lengths of the first, second and third n-fingers 272A, 272B and 272C, respectively, and A11, Al2 and A13 are cross-sectional areas of the first, second and third n-fingers 272A, 272B and 272C, respectively.

Accordingly, if the fist and third n-fingers 272A and 272C are longer than the second n-finger 272B as shown in FIG. 3, the cross-sectional areas A11 and A13 of the first and third n-fingers 272A and 272C are controlled to be greater than the cross-sectional area A12 of the second n-finger 272B so that the first and third n-fingers 272A and 272C have the same resistance as the second n-finger 272B. As such, it is possible to apply the same current uniformly across each of the n-fingers 272A, 272B and 272C so that the current spreading to the active layer (not shown) can be improved. Such a method for controlling the lengths and the cross-sectional areas of the n-fingers 272A, 272B and 272C according to Equation 3 so that the n-fingers 272A, 272B and 272C have the same resistance R is not limited to the n-electrode pattern 270. But the method can also be applied to the p-fingers 282A, 282B, 282C and 282D of the p-electrode pattern 280.

In addition, the method can also be applied to a horizontal-type nitride semiconductor light-emitting device according to still another embodiment of the present invention. That is, the method can also be applied to an electrode pattern including a plurality of fingers having different lengths from one another so that all the fingers have the same resistance.

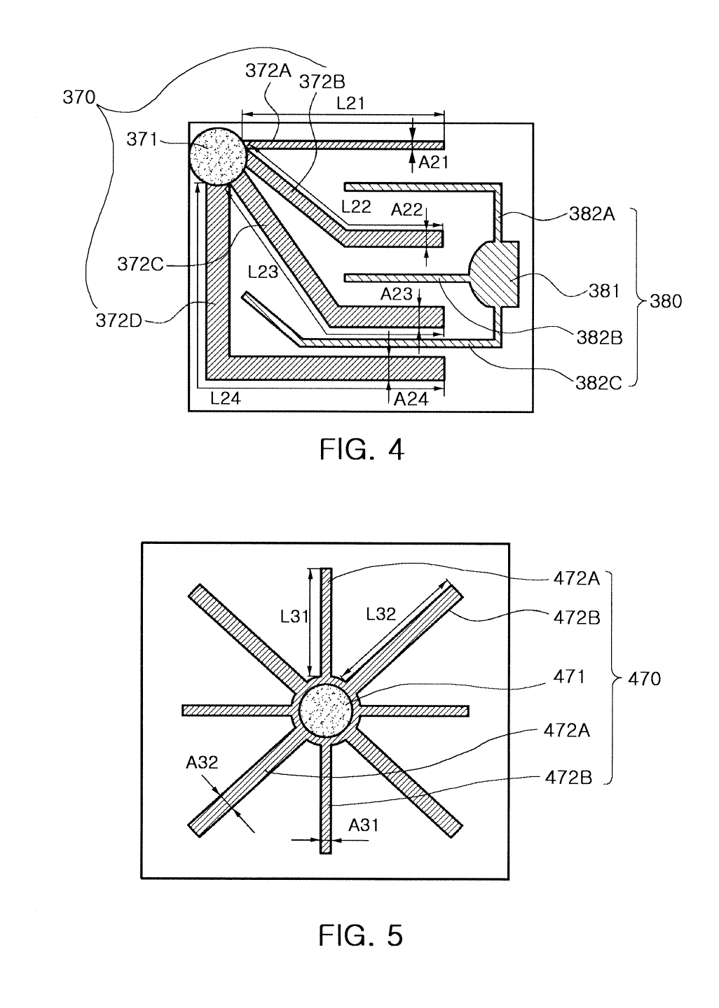

FIG. 4 is a schematic view of the electrode patterns of the horizontal type nitride semiconductor light-emitting device according to the still another embodiment of the present invention. FIG. 4 illustrates a p-electrode pattern 380 disposed on a p-type nitride layer (not shown) and an n-electrode pattern 370 disposed on an exposed region of an n-type nitride layer in the horizontal type nitride semiconductor light-emitting device.

Referring to FIG. 4, the horizontal type nitride semiconductor light-emitting device may include the p-electrode pattern 380 disposed on the p-type nitride layer (not shown), and the n-electrode pattern 370 disposed on the exposed region of the n-type nitride layer (not shown). The p-electrode pattern 380 may include a p-pad 381 disposed on the p-type nitride layer (at a right side of a top surface of the nitride semiconductor light-emitting device), and first, second and third p-fingers 382A, 382B and 382C extending from the p-pad 381 toward the left side of the top surface. The n-electrode pattern 370 may include an n-pad 371 disposed on the exposed region of the n-type nitride layer (at an upper left corner of the top surface), and first, second, third and fourth p-fingers 372A, 372B, 372C and 372D extending from the n-pad 371 toward the right side of the top surface.

The n-fingers 372A, 372B, 372C and 372D and the p-fingers 382A, 382B and 382C may extend alternatingly. The n-fingers 372A, 372B, 372C and 372D may extend to respective lengths L21, L22, L23 and L24 which are different from one another.

In a specific, the first n-finger 372A may extend horizontally along an edge of the top surface. The second n-finger 372B may slope down and then extend horizontally between the first p-finger 382A and the second p-finger 383B. The third n-finger 372C may slope down and then extend horizontally between the second p-finger 382B and the third p-finger 382C. The fourth n-finger 372D may extend vertically and then horizontally along edges of the top surface.

Here, the first to fourth n-fingers 372A to 372D may have lengths L21, L22, L23 and L24 different from one another. For example, the lengths of the n-fingers may increase gradually from the first n-finger 372A to the fourth n-finger 372D. In such a case, the resistances thereof may also increase gradually from the first n-finger 372A to the fourth n-finger 372D because the resistance increases with the length. Therefore, in order to make the n-fingers 372A to 372D have the same resistance R, cross-sectional areas thereof need to be controlled properly on the basis of Equation 1, as described above. That is, the lengths and the cross-sectional areas of the n-fingers 372A to 372D of the same material, i.e., of the same resistivity need to be controlled to satisfy the following relation

$$\frac{L 21}{A 21} = \frac{L 22}{A 22} = \frac{L 23}{A 23} = \frac{L 24}{A 24} \qquad ( 4 )$$

where L21, L22, L23 and L24 are lengths of the first, second, third and fourth n-fingers 372A, 372B, 372C and 372D, respectively, and A21, A22, A23 and A24 are cross-sectional areas of the first, second, third and fourth n-fingers 372A, 372B, 372C and 372D, respectively.

Accordingly, if the lengths of the n-fingers increase from the first n-finger 372A to the fourth n-finger 372D as shown in FIG. 4, the cross-sectional areas A21, A22, A23 and A24 of the n-fingers are controlled to increase from the first n-finger 372A to the fourth n-finger 372D so that the n-fingers 372A to 372D have the same resistance. As such, it is possible to apply the same current uniformly across the first to fourth n-fingers 372A to 372D so that the current spreading to the active layer (not shown) can be improved.

Surely, such a method for controlling the lengths and the cross-sectional areas of the n-fingers 372A, 372B, 372C and 372D according to Equation 4 so that the n-fingers 372A, 372B, 372C and 372D have the same resistance R is not limited to the n-electrode pattern 370. But the method can also be applied to the p-fingers 382A, 382B and 382C of the p-electrode pattern 380.

In addition, the method is not limited to the horizontal type nitride semiconductor light-emitting device. But the method can also be applied to vertical type nitride semiconductor light-emitting devices as shown in FIGS. 5 to 7.

Hereinafter, electrode patterns of a vertical type nitride semiconductor light-emitting device according to even another embodiment of the present invention will be described with reference to FIG. 5.

FIG. 5 is a schematic view of the electrode pattern of the vertical type nitride semiconductor light-emitting device according to the even another embodiment of the present invention. The electrode pattern shown in FIG. 5 maybe either a p-electrode pattern disposed on a p-type nitride layer (not shown) or an n-electrode pattern disposed on an exposed region of an n-type nitride layer in the vertical type nitride semiconductor light-emitting device.

Surely, the vertical type nitride semiconductor light-emitting device may include the p-electrode pattern disposed on the p-type nitride layer (not shown) and the n-electrode pattern disposed on the exposed region of the n-type nitride layer. However, FIG. 5 illustrates only one of the electrode patterns for clarity of illustration, and it will be assumed that the electrode pattern is an n-type electrode pattern.

Referring to FIG. 5, the vertical type nitride semiconductor light-emitting device may include an n-pad 471 disposed at a center of atop surface of the n-type nitride layer. The vertical type nitride semiconductor light-emitting device further includes a plurality of first n-fingers 472A and a plurality of second n-fingers 472B, which extend alternatingly and radially from the n-pad 471.

The first n-fingers 472A may extend from the n-pad 471 toward edges of the vertical type nitride semiconductor light-emitting device. The second n-fingers 472B may extend from the n-pad 471 toward corners of the vertical type nitride semiconductor light-emitting device between the first n-fingers 472A. The length L31 of the first n-fingers 472A is different from the length L32 of the second n-fingers 472B.

In such a case, the first n-fingers 472A have a resistance greater than that of the second n-fingers 472B because the resistance increases with the length. Therefore, in order to make the first n-fingers 472A and the second n-fingers 472B have the same resistance R, cross-sectional areas thereof need to be controlled properly on the basis of Equation 1, as described above. That is, the lengths and the cross-sectional areas of the first and second n-fingers 472A and 472B of the same material, i.e., of the same resistivity need to be controlled to satisfy the following relation

$$\frac{L 31}{A 31} = \frac{L 32}{A 32} \qquad ( 5 )$$

where L31 and L32 are lengths of the first and second n-fingers 472A and 472B, respectively, and A31 and A32 are cross-sectional areas of the first and second n-fingers 472A and 472B, respectively.

Accordingly, if the second n-finger 472B is longer than the first n-finger 472A as shown in FIG. 5, the cross-sectional area A32 of the second n-finger 472B is controlled to be greater than the cross-sectional area A31 of the first n-finger 472A so that the first n-finger 472A and the second n-finger 472B have the same resistance. As such, it is possible to apply the same current uniformly across each of the first and second n-fingers 472A and 472B so that the current spreading to the active layer (not shown) can be improved. Such a method for controlling the lengths and the cross-sectional areas of the n-fingers 472A and 472B according to Equation 5 so that the n-fingers 472A and 472B have the same resistance R is not limited to the n-electrode pattern 470. But the method can also be applied to p-fingers of the p-electrode pattern disposed on the p-type nitride layer to correspond to the n-electrode pattern.

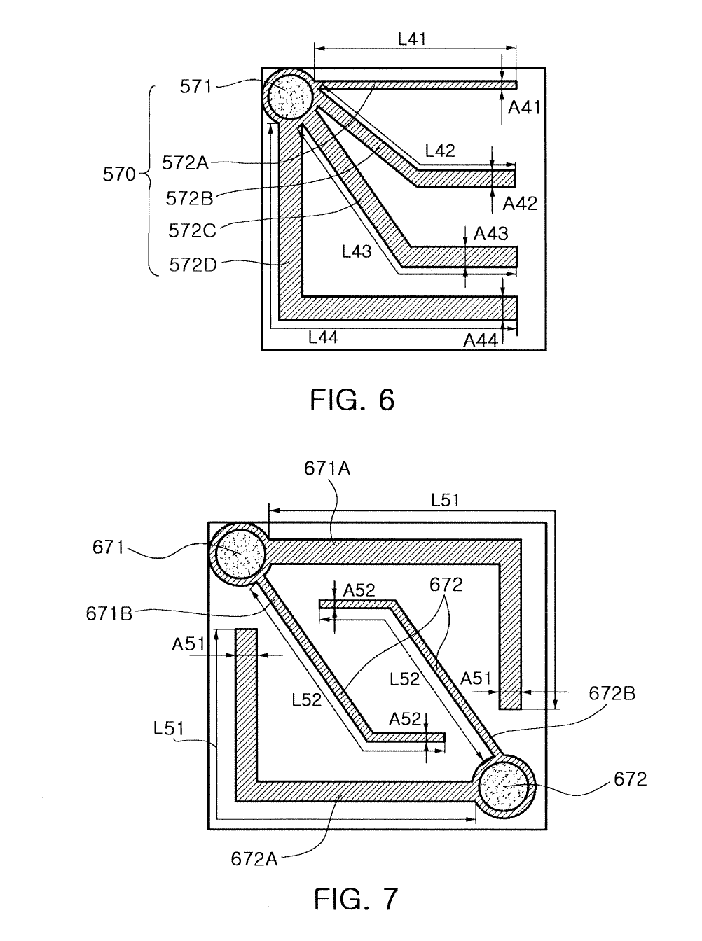

Hereinafter, electrode patterns of a vertical type nitride semiconductor light-emitting device according to yet another embodiment of the present invention will be described with reference to FIG. 6.

FIG. 6 is a schematic view of the electrode pattern of the vertical type nitride semiconductor light-emitting device according to the yet another embodiment of the present invention. The vertical type nitride semiconductor light-emitting device may include a p-electrode pattern disposed on a p-type nitride layer (not shown) and an n-electrode pattern disposed on an exposed region of an n-type nitride layer. However, FIG. 6 illustrates only the n-electrode pattern disposed on the n-type nitride layer for clarity of illustration.

Referring to FIG. 6, the vertical type nitride semiconductor light-emitting device may include an n-pad 571 disposed at an upper left corner of a top surface of the n-type nitride layer. The vertical type nitride semiconductor light-emitting device may further include four n-fingers 572A, 572B, 572C and 572D extending from the n-pad 571.

In a specific, a first n-finger 572A, a second n-finger 572B, a third n-finger 572C and a fourth n-finger 572D may extend from the n-pad 571 at the upper left corner to a right edge of the top surface of the n-type nitride layer. The first n-finger 572A may extend horizontally along an edge of the top surface. The second n-finger 572B may slope down and then extend horizontally below the first n-finger 572A. The third n-finger 572C may slope down and then extend horizontally below the second n-finger 572B. The fourth n-finger 572D may extend vertically and then horizontally along edges of the top surface.

Here, the first to fourth n-fingers 572A to 572D may have lengths L41, L42, L43 and L44 different from one another. For example, the lengths of the n-fingers may increase gradually from the first n-finger 572A to the fourth n-finger 572D. In such a case, the resistances thereof may also increase gradually from the first n-finger 572A to the fourth n-finger 572D because the resistance increases with the length. Therefore, in order to make the n-fingers 572A to 572D have the same resistance R, cross-sectional areas thereof need to be controlled properly on the basis of Equation 1, as described above. That is, the lengths and the cross-sectional areas of the n-fingers 572A to 572D of the same material, i.e., of the same resistivity need to be controlled to satisfy the following relation

$$\frac{L 41}{A 41} = \frac{L 42}{A 42} = \frac{L 43}{A 43} = \frac{L 44}{A 44} \qquad ( 6 )$$

where L41, L42, L43 and L44 are lengths of the first, second, third and fourth n-fingers 572A, 572B, 572C and 572D, respectively, and A41, A42, A43 and A44 are cross-sectional areas of the first, second, third and fourth n-fingers 572A, 572B, 572C and 572D, respectively.

Accordingly, if the lengths of the n-fingers increase from the first n-finger 572A to the fourth n-finger 572D as shown in FIG. 6, the cross-sectional areas A41, A42, A43 and A44 of the n-fingers are controlled to increase from the first n-finger 572A to the fourth n-finger 572D so that the n-fingers 572A to 572D have the same resistance. As such, it is possible to apply the same current uniformly across the first to fourth n-fingers 572A to 572D so that the current spreading to the active layer (not shown) can be improved.

Surely, such a method for controlling the lengths and the cross-sectional areas of the n-fingers 572A, 572B, 572C and 572D according to Equation 6 so that the n-fingers 572A, 572B, 572C and 572D have the same resistance R is not limited to the n-electrode pattern 570. But the method can also be applied to p-fingers of the p-electrode pattern disposed on a p-type nitride layer.

Hereinafter, electrode patterns of a vertical type nitride semiconductor light-emitting device according to further another embodiment of the present invention will be described with reference to FIG. 7.

FIG. 7 is a schematic view of the electrode pattern of the vertical type nitride semiconductor light-emitting device according to the further another embodiment of the present invention. The vertical type nitride semiconductor light-emitting device may include a p-electrode pattern disposed on a p-type nitride layer (not shown) and an n-electrode pattern disposed on an exposed region of an n-type nitride layer. However, FIG. 7 illustrates only two n-electrode patterns disposed on the n-type nitride layer for clarity of illustration.

Referring to FIG. 7, the vertical type nitride semiconductor light-emitting device may include a first n-pad 671 disposed at an upper left corner and a second n-pad 672 disposed at a lower right corner on a top surface of the nitride layer. The vertical type nitride semiconductor light-emitting device may further include n-fingers 671A and 671B extending from the first n-pad 671 to the second n-pad 672, and n-fingers 672A and 672B extending from the second n-pad 672 to the first n-pad 671.

In a specific, the first and second n-fingers 671A and 671B and the third and fourth n-fingers 672A and 672B may extend alternately from the respective n-pads 671 and 672. That is, the first n-finger 671A may extend horizontally and then vertically along edges of the top surface. The second n-finger 671B may slope down and then extend horizontally between the fourth n-finger 6728 and the third n-finger 672A. The third n-finger 672A may extend horizontally and then vertically along edges of the top surface. The fourth n-finger 672B may slope up and then extend horizontally between the first n-finger 671A and the second n-finger 671B.

Here, the first and third n-fingers 671A and 672A may have a length L51 different from the length L52 of the second and fourth n-fingers 671B and 672B. For example, the length L51 of the first and third n-fingers 671A and 672A may be greater than the length L52 of the second and fourth n-fingers 671B and 672B. In such a case, the first and third n-fingers 671A and 672A have a resistance greater than that of the second and fourth n-fingers 671B and 672B. Therefore, in order to make the n-fingers 671A, 671B, 672A and 672B have the same resistance R, cross-sectional areas thereof need to be controlled properly on the basis of Equation 1, as described above. That is, the lengths and the cross-sectional areas of the n-fingers 671A, 671B, 672A and 672B of the same material, i.e., of the same resistivity need to be controlled to satisfy the following relation

$$\frac{L 51}{A 51} = \frac{L 52}{A 52} \qquad ( 7 )$$

where L51 is a length of the first and third n-fingers 671A and 672A, L52 is a length of the second and fourth n-fingers 671B and 672B, A51 is a cross-sectional area the first and third n-fingers 671A and 672A, and A52 is a cross-sectional area of the second and fourth n-fingers 671B and 672B.

Accordingly, if the length L51 of the first and third n-fingers 671A and 672A is greater than the length L52 of the second and fourth n-fingers 671B and 672B as shown in FIG. 7, the cross-sectional area A51 of the first and third n-fingers 671A and 672A are controlled to be greater than the cross-sectional area A52 of the second and fourth n-fingers 671B and 672B so that the n-fingers 671A, 671B, 672A and 672B have the same resistance. As such, it is possible to apply the same current uniformly across the first to fourth n-fingers 671A, 671B, 672A and 672B so that the current spreading to the active layer (not shown) can be improved.

Surely, such a method for controlling the lengths and the cross-sectional areas of the n-fingers 671A, 671B, 672A and 672B so that the n-fingers 671A, 671B, 672A and 672B have the same resistance R may also be applied to the case where all of the four n-fingers 671A, 671B, 672A and 672B have respective lengths different from one another.

In addition, the method for controlling the lengths and the cross-sectional areas of the n-fingers 671A, 671B, 672A and 672B so that the n-fingers 671A, 671B, 672A and 672B have the same resistance R is not limited to the n-electrode pattern 670. But the method can also be applied to the p-fingers of the p-electrode pattern disposed on a p-type nitride layer.

As described above, the n-fingers and the p-fingers can have the same resistance so that the same current is applied uniformly across each of the n-fingers and the p-fingers. As a result, it is possible to improve the current spreading to the active layer, and thus to improve the light emission efficiency of the nitride semiconductor light-emitting device.

While the present invention has been shown and described in connection with the exemplary embodiments, it will be apparent to those skilled in the art that modifications and variations can be made without departing from the spirit and scope of the invention as defined by the appended claims.

1-11. (canceled)

12. A nitride semiconductor light-emitting device comprising:
an active layer having a multi-quantum-well structure between an n-type nitride layer and a p-type nitride layer;
a p-electrode pattern comprising one or more p-pads disposed on the p-type nitride layer, and a plurality of p-fingers extending from the p-pads; and
an n-electrode pattern comprising one or more n-pads disposed on an exposed region of the n-type nitride layer, and a plurality of n-fingers extending from the n-pads,
wherein the n-fingers have identical resistances, and the p-fingers have identical resistances to improve current spreading to the active layer,
wherein each of the p-fingers satisfies a relationship, R=ρL/A, where R, ρ, L and A are resistance in ohms, resistivity in ohm-cm, length in cm, and a cross-sectional area in cm² of the p-finger, respectively, so that the cross-sectional area A is proportional to the length L, and
wherein the p-fingers or the n-fingers comprise a plurality of fingers extending alternately and radially.

13. The nitride semiconductor light-emitting device of claim 12, wherein each of the n-fingers satisfies a relationship, R=ρL/A, where R, ρ, L and A are resistance in ohms, resistivity in ohm-cm, length in cm, and a cross-sectional area in cm² of the n-finger, respectively, so that the cross-sectional area A is proportional to the length L.

14. The nitride semiconductor light-emitting device of claim 12, wherein the n-fingers or the p-fingers each have at least one bent section.

15. The nitride semiconductor light-emitting device of claim 12, wherein the p-fingers comprise:
a first p-finger having a first length and a first cross-sectional area; and
a second p-finger having a second length greater than the first length,
wherein a second cross-sectional area of the second p-finger satisfies a relationship,
$$\frac{L 1}{A 1} = \frac{L 2}{A 2} ,$$
where L1, L2, A1 and A2 are the first length, the second length, the first cross-sectional area and the second cross-sectional area, respectively.

16. The nitride semiconductor light-emitting device of claims 12, wherein each of the p-fingers have different lengths, and each of the widths of the p-fingers is maintained so as to be even.

17. The nitride semiconductor light-emitting device of claim 12, wherein the n-fingers and the p-fingers are disposed alternately.

18. The nitride semiconductor light-emitting device of claim 12, wherein the n-fingers comprise:
a first n-finger having a first length and a first cross-sectional area;
a second n-finger having a second length greater than the first length; and
a third n-finger having a third length greater than the second length,
wherein a second cross-sectional area of the second p-finger and a third cross-sectional area of the third p-finger satisfy a relationship,
$$\frac{L 11}{A 11} = \frac{L 12}{A 12} = \frac{L 13}{A 13} ,$$
where L11, L12, L13, A11, A12 and A13 are the first length, the second length, the third length, the first cross-sectional area, the second cross-sectional area and the third cross-sectional area, respectively.
